(19) United States
(12) Patent Application Publication
(10) Pub. No.: US 2026/0126481 A1
(43) Pub. Date: May 7, 2026

(54) SEMICONDUCTOR DEVICE INCLUDING BONDING PADS AND METHOD FOR MEASURING CONTACT RESISTANCE OF BONDING PADS

(71) Applicant: SK hynix Inc., Gyeonggi-do (KR)

(72) Inventor: Heon Yong CHANG, Gyeonggi-do (KR)

(21) Appl. No.: 19/073,010

(22) Filed: Mar. 7, 2025

(30) Foreign Application Priority Data
Nov. 1, 2024 (KR) 10-2024-0153570

(51) Int. Cl. G01R 31/28; H01L 23/00; H01L 25/18; H10B 41/41; H10B 43/40; H10B 80/00; H10D 80/30

(52) U.S. Cl. CPC G01R 31/2856; H10B 80/00; H10D 80/30; H10W 90/00; H10B 41/41; H10B 43/40; H10W 90/792

(57) ABSTRACT

A semiconductor device including a first test pattern in which the first upper test pad, first upper test contacts, and first upper conductive layers connecting the first upper test contacts are sequentially connected, a second test pattern in which the second lower test pad, second lower test contacts, and second lower conductive layers connecting the second lower test contacts are sequentially connected, and a third test pattern including a third upper conductive layer, a third lower conductive layer, a third upper test contact, a third upper test pad, a third lower test pad, and a third lower test contact.

### CROSS-REFERENCE TO RELATED APPLICATION

The present application claims priority under 35 U.S.C. 119(a) to Korean patent application number 10-2024-0153570 filed on Nov. 1, 2024, which is incorporated herein by reference in its entirety.

### TECHNICAL FIELD

The embodiments of the present disclosure relate generally to semiconductor technology and, more particularly to a semiconductor device including bonding pads and a method for measuring contact resistance of bonding pads.

### BACKGROUND

A memory device is an important component in an electronics industry owing to their characteristics such as miniaturization, multi-functionality, and/or low manufacturing cost. As the electronics industry develops, memory devices are gradually becoming more highly integrated. In order to achieve high integration of the memory device, a technology has been proposed that forms the various semiconductor device components and circuits in two separate wafers and then bonding the two wafers together in a vertical direction by using wafer bonding technology. This technology is rather fairly new and further improvements are needed.

### SUMMARY

Various embodiments of the present disclosure provide a semiconductor device including bonding pads and method for measuring contact resistance of bonding pads capable of accurately measuring resistance between bonding pads.

Various embodiments of the present disclosure provide a semiconductor device including a memory chip including a cell bonding pad disposed in a cell region, and upper test pads disposed outside the cell region and including first, second, and third upper test pad; a circuit chip including a peripheral bonding pad disposed in the cell region and bonded to the cell bonding pad, and lower test pads disposed outside the cell region and including first, second, and third lower test pad; and test patterns disposed outside the cell region, each of which includes at least a part of the upper test pads and the lower test pads. In this case, the test patterns may include a first test pattern in which the first upper test pad, first upper test contacts connected to each of the first upper test pads, and first upper conductive layers connecting the first upper test contacts connected to different first upper test pads are sequentially connected; a second test pattern in which the second lower test pad, second lower test contacts connected to each of the second lower test pads, and second lower conductive layers connecting the second lower test contacts connected to different second lower test pads are sequentially connected; and a third test pattern including a third upper conductive layer, a third lower conductive layer, and a third upper test contact connecting between the third upper conductive layer and the lower conductive layer, a third upper test pad, a third lower test pad, and a third lower test contact.

Various embodiments of the present disclosure may provide a semiconductor device including a memory chip including cell bonding pads disposed in a cell region, and upper test pads disposed outside the cell region; a circuit chip including peripheral bonding pads disposed in the cell region and bonded to the cell bonding pads, and lower test pads disposed outside the cell region; and test patterns disposed outside the cell region and including at least a part of the upper test pads and the lower test pads. At least one of the test patterns may include a part of the upper test pads and a part of the lower test pads. Each of the part of the test pads may be bonded to two of the part of the lower test pads, and each of the part of the lower test pads may be bonded to two of the part of the test pads.

Various embodiments of the present disclosure may provide a method of measuring contact resistance for determining bonding strength between a cell bonding pad and a peripheral bonding pad bonded to each other using at least a part of upper test pads including a first upper test pad, a second upper test pad, and a third upper test pad, and lower test pads including a first lower test pad, a second lower test pad, and a third lower test pad. The method may include measuring a first resistance between the first upper test pad and a first upper test contact connected to the first upper test pad; measuring a second resistance between the second lower test pad and a second lower test contact connected to the second lower test pad; measuring a third resistance between a third upper test contact and the third lower test contact in a test pattern in which the third upper test contact, the third upper test pad, the third lower test pad, and the third lower test contact are sequentially connected; and measuring contact resistance between the cell bonding pad and the peripheral bonding pad by subtracting the first and second resistances from the third resistance, and evaluating the bonding strength between the cell bonding pad and the peripheral bonding pad based on the contact resistance.

According to some embodiments of the present disclosure, it is possible to accurately measure a contact resistance of bonding pads.

These and other features and advantages of the embodiments of the present disclosure will become better understood from the detailed description of the embodiments in conjunction with the following drawings.

### BRIEF DESCRIPTION OF THE DRAWINGS

FIG. 1 illustrates a planar structure of a semiconductor device according to embodiments of the present disclosure.

FIG. 2 illustrates a cross-sectional structure of a semiconductor device according to embodiments of the present disclosure.

FIGS. 3 to 9 illustrate cross-sectional structures of semiconductor devices according to embodiments of the present disclosure.

FIG. 10 illustrates another planar structure of a semiconductor device according to embodiments of the present disclosure.

### DETAILED DESCRIPTION

Hereinafter, various embodiments of the present disclosure will be described in detail with reference to the accompanying drawings.

In the attached drawings, two directions parallel to an upper surface of a substrate are defined as a first direction FD and a second direction SD, respectively, and a direction protruding vertically from the upper surface of the substrate is defined as a third direction VD. The first direction FD and the second direction SD may be substantially perpendicular to each other. The third direction VD may be a direction perpendicular to the first direction FD and the second direction SD. In this specification, ‘vertical’ or ‘vertical direction’ will be used to have substantially the same meaning as the third direction VD. The direction indicated by an arrow in the drawings and its opposite direction may indicate the same direction.

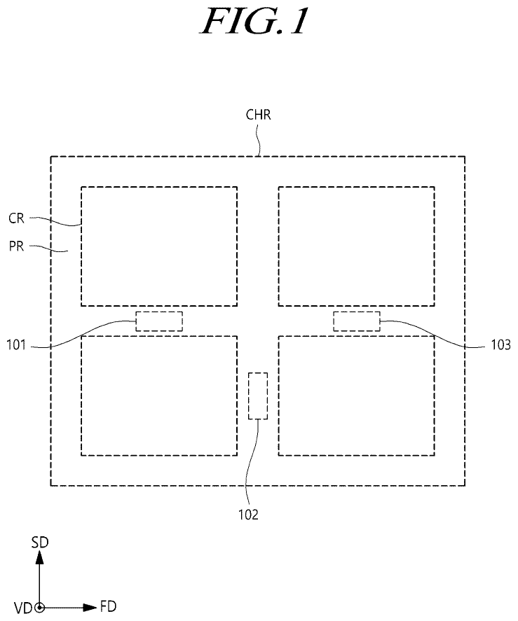

FIG. 1 illustrates a planar structure of a semiconductor device according to embodiments of the present disclosure.

Referring to FIG. 1, the semiconductor device may include a chip region CHR. The semiconductor device may be one of a dynamic random access memory (DRAM), a static random access memory (SRAM), a flash memory, a magnetoresistive random access memory (MRAM), a phase-change random access memory (PRAM), a ferroelectric random access memory (FRAM), a resistive random access memory (RRAM), or a combination thereof. In an embodiment, the semiconductor device may be a memory device including a NAND flash memory cell. Hereinafter, there is described an example where the semiconductor device is a memory device including a NAND flash memory cell.

The chip region CHR may include a cell region CR and a peripheral region PR. The cell region CR may be a region where a memory cell array is disposed. The peripheral region PR may be disposed around the cell region CR and may be a region where various circuits connected to the memory cell array are disposed. In an embodiment, the chip region CHR may include four cell regions CR spaced apart from each other, with each cell region CR being surrounded by a peripheral region PR. The four cell regions CR may each have a generally rectangular, or square shape and may be arranged in a matrix of rows and columns, for example, as illustrated in FIG. 1, a 2 by 2 matrix with two cell regions CR in each row and in each column forming together with an outer peripheral region PR an overall rectangular, or square region. This arrangement is an example of one possible configuration, and, therefore, the embodiments may not be limited in this way. For example, each of the four cell regions CR may have a circle shape.

A plurality of test patterns, for example, test patterns 101, 102 and 103 may be disposed in the peripheral region PR. The test patterns 101, 102 and 103 may include a first test pattern 101, a second test pattern 102, and a third test pattern 103. The test patterns 101, 102 and 103 may include monitoring patterns or various test patterns for monitoring a defect of a semiconductor device. For example, the test patterns 101, 102 and 103 may be patterns configured for measuring resistance between metal layers included in the semiconductor device. Each of the test patterns 101, 102 and 103 may be disposed at an arbitrary position within the peripheral region PR. In FIG. 1, the test patterns 101, 102 and 103 are illustrated as being disposed between different cell regions CR, but the positions at which the test patterns 101, 102 and 103 are arranged are not limited thereto. For example, one or more test patterns may be disposed at the outer section of the peripheral circuit that surrounds all four cell regions CR.

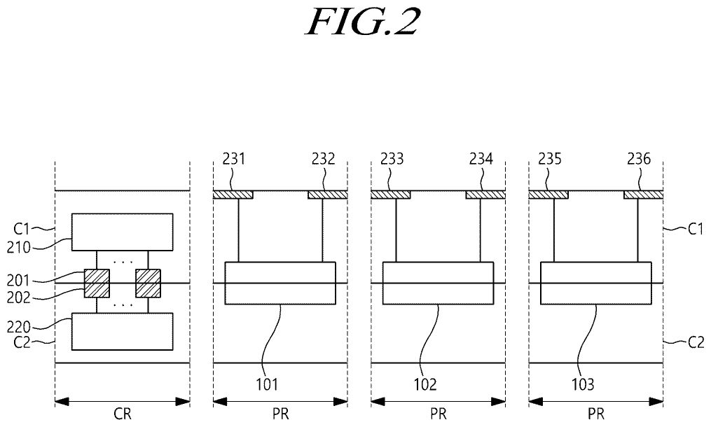

FIG. 2 illustrates a cross-sectional structure of a semiconductor device according to embodiments of the present disclosure.

Referring to FIG. 2, the semiconductor device may include a memory chip C1, a circuit chip C2, and a test pattern 101, 102 and 103.

The memory chip C1 and the circuit chip C2 may be semiconductor chips manufactured from different wafers, respectively. In the cell region CR, the memory chip C1 may include a memory cell array 210 and a cell bonding pad 201. The circuit chip C2 may include a logic circuit 220 and a peripheral bonding pad 202. The logic circuit 220 may include circuits for transmitting various voltages and signals to the memory cell array 210. At least a portion (not shown) of the logic circuit 220 may also be disposed in the peripheral region PR. A lower surface (i.e., a bottom surface) of the cell bonding pad 201 may contact an upper surface (i.e., a top surface) of the peripheral bonding pad 202. The memory chip C1 and the circuit chip C2 may be bonded through the cell bonding pad 201 and the peripheral bonding pad 202. In an embodiment, the process of bonding the memory chip C1 and the circuit chip C2 may include a wafer bonding process.

In the peripheral region PR, the memory chip C1 may include probing pads 231, 232, 233, 234, 235 and 236. The probing pads may include a first probing output pad 231, a first probing input pad 232, a second probing output pad 233, a second probing input pad 234, a third probing output pad 235, and a third probing input pad 236. The probing pads 231, 232, 233, 234, 235 and 236 may be connected to the outside of the semiconductor device so that various voltages or signals may be supplied from the outside of the semiconductor device to the semiconductor device through the probing pads 231, 232, 233, 234, 235 and 236. In an embodiment, the probing pads 231, 232, 233, 234, 235 and 236 may extend from the peripheral region PR to the outside of the chip region CHR.

Each of the test patterns 101, 102 and 103 may be connected to the probing pads 231, 232, 233, 234, 235 and 236. For example, the first test pattern 101 may be connected to the first probing input pad 232 and the first probing output pad 231, the second test pattern 102 may be connected to the second probing input and output pads 233 and 234, and the third test pattern 103 may be connected to the third probing input and output pads 235 and 236. The test patterns 101, 102 and 103 may be arranged across the memory chip C1 and the circuit chip C2. For example, at least a part of the components included in each of the test patterns 101, 102 and 103 may be included in the memory chip C1, and at least the other part of the components may be included in the circuit chip C2.

Each of the test patterns 101, 102 and 103 may be patterns configured for measuring different resistances. For example, the first test pattern 101 may be configured for measuring contact resistance between the cell bonding pad 201 and a contact connected to the upper surface of the cell bonding pad 201. The second test pattern 102 may be configured for measuring contact resistance between a peripheral bonding pad 202 and a contact connected to the lower surface (also referred to as the bottom surface) of the peripheral bonding pad 202. The third test pattern 103 may be configured for measuring resistance between a contact connected to the upper surface of the cell bonding pad 201 and a contact connected to the lower surface of the peripheral bonding pad 202. Alternatively, the third test pattern 103 may be configured for measuring contact resistance between the cell bonding pad 201 and the peripheral bonding pad 202. Although the test patterns in FIG. 2 are illustrated as including three different test patterns, the number of test patterns is not limited thereto.

Embodiments of the present disclosure provide a method for obtaining a contact resistance between a cell bonding pad 201 and a peripheral bonding pad 202 by using at least one resistance value among a first resistance measured from a first test pattern 101, a second resistance measured from a second test pattern 102, and a third resistance measured from a third test pattern 103. In addition, the degree of contact or bonding between the cell bonding pad 201 and the peripheral bonding pad 202 may be determined based on the contact resistance value between the cell bonding pad 201 and the peripheral bonding pad 202. The “degree of contact” as this term is used herein refers to the extent or quality of the connection between the cell bonding pad 201 and the peripheral bonding pad 202. The degree of contact may affect the electrical performance, as a good degree of contact usually means lower contact resistance and better conductivity, whereas a poor degree of contact could lead to higher resistance and potential issues with signal transmission or power delivery.

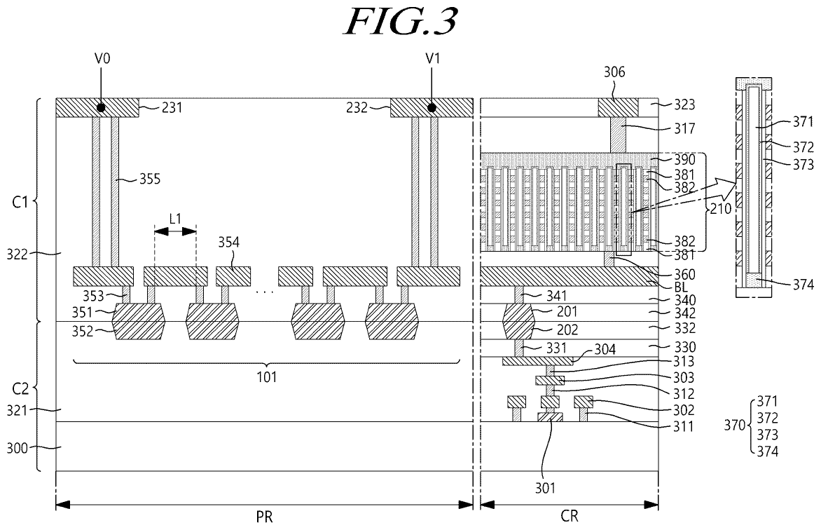

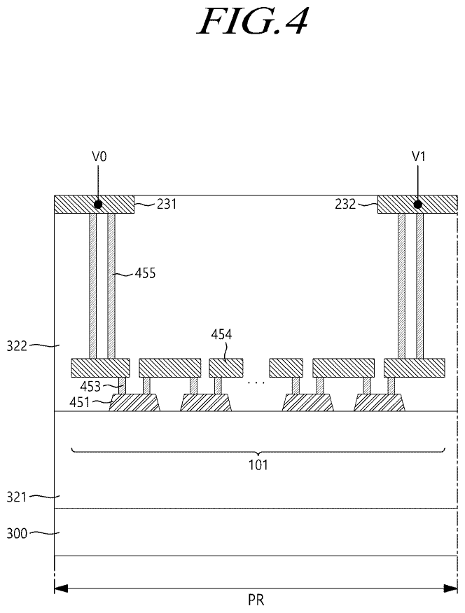

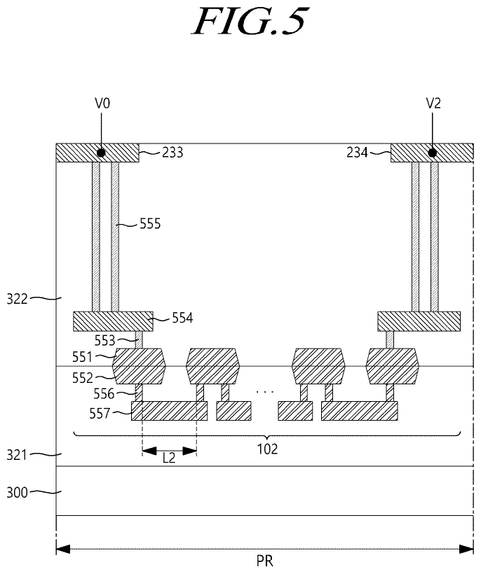

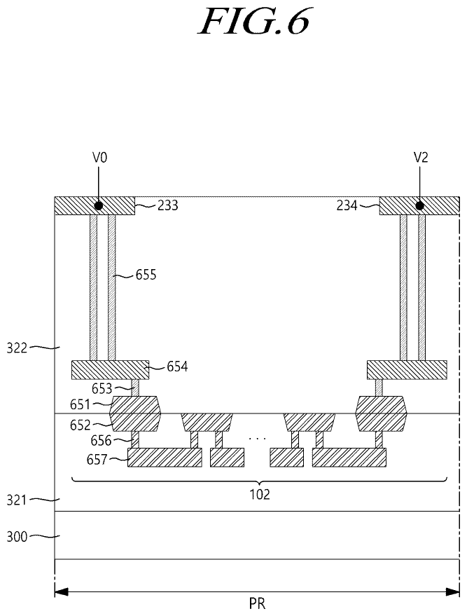

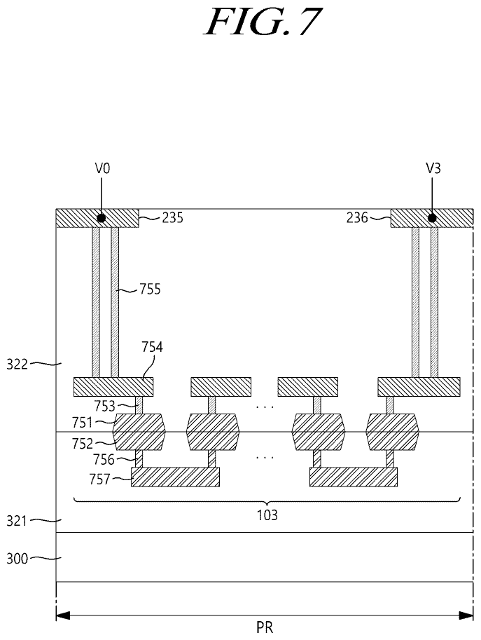

FIGS. 3 to 9 illustrate cross-sectional structures of semiconductor devices according to embodiments of the present disclosure. FIGS. 3 and 4 illustrate the cross-sectional structure of a semiconductor device including a first test pattern. FIGS. 5 and 6 illustrate the cross-sectional structure of a semiconductor device including a second test pattern. FIGS. 7 to 9 illustrate the cross-sectional structure of a semiconductor device including a third test pattern.

Referring to FIG. 3, the semiconductor device may include a substrate 300, a gate 301, wirings 302, 303, 304 and 306, contacts 311, 312, 313 and 317, a first insulating layer 321, a second insulating layer 330, a peripheral bonding contact 331, a second bonding insulating layer 332, a peripheral bonding pad 202, a third insulating layer 340, a cell bonding contact 341, a first bonding insulating layer 342, a cell bonding pad 201, a bit line BL, a bit line contact 360, a memory cell array 210, a fourth insulating layer 322, a fifth insulating layer 323, a first probing output pad 231, a first probing input pad 232, a connection contact 355, and a first test pattern 101.

The substrate 300 may include a semiconductor substrate such as a silicon wafer or a silicon-on-insulator (SOI) wafer. The substrate 300 may include a III-V group semiconductor substrate, for example, a compound semiconductor substrate such as GaAs. The substrate 300 may include single crystal silicon, polysilicon, amorphous silicon, single crystal silicon germanium, polycrystalline silicon germanium, carbon-doped silicon, or a combination thereof.

The gate 301, the contacts 311, 312 and 313, the wirings 302, 303 and 304, and the first insulating layer 321 may be disposed on the substrate 300. The contacts 311, 312 and 313 may be disposed between the wirings 302, 303 and 304, or between a first wiring 302 and the substrate 300. The contacts 311, 312 and 313 may be electrically connected to the wirings 302, 303 and 304. The gate 301, the first contact 311, and the first wiring 302 may form one transistor.

The gate 301, the contacts 311, 312 and 313, and the wirings 302, 303 and 304 may include a conductive material such as a metal, a metal oxide, a metal nitride, a metal silicide, polysilicon, a conductive carbon, or a combination thereof. The first insulating layer 321 may include silicon oxide, silicon nitride, silicon oxynitride, a high-k dielectric, or a combination thereof.

In the cell region CR, the peripheral bonding contact 331 and the second insulating layer 330 are disposed on the third wiring 304. The peripheral bonding contact 331 may be disposed within the second insulating layer 330. The peripheral bonding contact 331 may be connected to the corresponding third wiring 304. The second bonding insulating layer 332 and the peripheral bonding pad 202 may be disposed on the peripheral bonding contact 331 and the second insulating layer 330. The peripheral bonding pad 202 may be disposed within the second bonding insulating layer 332. The peripheral bonding pad 202 may be connected to the corresponding peripheral bonding contact 331. In the illustrated embodiment of FIG. 3, the top surface of the peripheral bonding pad 202 may form substantially the same plane as the top surface of the second bonding insulating layer 332.

A first bonding insulating layer 342 and the cell bonding pad 201 may be disposed on the second bonding insulating layer 332. The cell bonding pad 201 may be disposed within the first bonding insulating layer 342. In an embodiment, a lower surface of the cell bonding pad 201 may be substantially coplanar with a lower surface of the first bonding insulating layer 342. A lower surface of the cell bonding pad 201 may contact an upper surface of a corresponding one of the peripheral bonding pads 202. In an embodiment, the cell bonding pad 201 may be bonded to the peripheral bonding pad 202. A lower surface of the first bonding insulating layer 342 may contact a lower surface of the second bonding insulating layer 332. In an embodiment, the first bonding insulating layer 342 may be bonded to the second bonding insulating layer 332.

A third insulating layer 340 and a cell bonding contact 341 may be disposed on the cell bonding pad 201 and the first bonding insulating layer 342. The cell bonding contact 341 may be connected to a corresponding one of the cell bonding pads 201.

The cell bonding contact 341, the peripheral bonding contact 331, the cell bonding pad 201, and the peripheral bonding pad 202 may include a conductive material such as a metal, a metal oxide, a metal nitride, a metal silicide, polysilicon, a conductive carbon, or a combination thereof. The second insulating layer 330, the third insulating layer 340, the first bonding insulating layer 342, and the second bonding insulating layer 332 may include silicon oxide, silicon nitride, silicon oxynitride, a high-k dielectric, or a combination thereof. In an embodiment, the first bonding insulating layer 342 and the second bonding insulating layer 332 may include silicon carbon nitride.

In the cell region CR, a bit line BL may be disposed on a third insulating layer 340. A bit line contact 360 and a fourth insulating layer 322 may be disposed on the bit line BL. The bit line contact 360 may be connected to a corresponding one of the bit lines BL. A memory cell array 210 may be disposed on the bit line contact 360 and the fourth insulating layer 322.

The memory cell array 210 may include an interlayer insulating layer 381 and an electrode layer 382 alternately stacked in a vertical direction, a channel structure 370, and a source plate 390.

The channel structure 370 may pass through the interlayer insulating layer 381 and the electrode layer 382. The channel structure 370 may extend into the source plate 390. The upper surface of the channel structure 370 may be disposed higher than the lower surface of the source plate 390. The lower surface of the channel structure 370 may form substantially the same plane as the lower surface of the interlayer insulating layer 381 disposed at the lowest position of the memory cell array 210.

The channel structure 370 may include a core layer 371, a channel pattern 372, a gate insulating layer 373, and a drain pad 374. The drain pad 374 may contact the upper surface of the bit line contact 360. The core layer 371 may be disposed on the drain pad 374. The channel pattern 372 may surround the side surface and the lower surface of the core layer 371. The channel pattern 372 may extend into the inside of the source plate 390. A gate insulating layer 373 may surround the side surface of the channel pattern 372 and the drain pad 374. One electrode layer 382, the gate insulating layer 373, and a portion of the channel pattern 372 overlapping with the one electrode layer 382 in the first direction FD or the second direction SD may constitute one memory cell.

The source plate 390 may be disposed on the interlayer insulating layer 381 and the channel structure 370 located at the uppermost portion of the memory cell array 210.

A fourth contact 317 may be disposed on the source plate 390. The fourth contact 317 may be connected to the source plate 390. A fifth insulating layer 323 and a fourth wiring 306 may be disposed on the fourth contact 317. The fourth wiring 306 may be connected to the fourth contact 317.

The bit line BL, the bit line contact 360, the electrode layer 382, the drain pad 374, the fourth contact 317, and the fourth wiring 306 may include a conductive material such as a metal, a metal oxide, a metal nitride, a metal silicide, polysilicon, a conductive carbon, or a combination thereof. The channel pattern 372 and the source plate 390 may include a semiconductor material such as polysilicon. The fourth insulating layer 322, the interlayer insulating layer 381, a seventh insulating layer 357, and a fifth insulating layer 323 may include silicon oxide, silicon nitride, silicon oxynitride, a low-k dielectric, a high-k dielectric, or a combination thereof.

In the peripheral region PR, the first insulating layer 321 may be disposed on the substrate 300. On the first insulating layer 321, a fourth insulating layer 322, a first test pattern 101, a connection contact 355, a first probing output pad 231, and a first probing input pad 232 may be disposed.

The first test pattern 101 may include a first upper test pad 351, a first lower test pad 352, a first upper test contact 353, and a first upper conductive layer 354. The first upper test pad 351 may be disposed at a lower edge region of the memory chip C1 with its lower surface being coplanar with the lower surface of the memory chip C1. The first lower test pad 352 may be disposed at an upper edge region of the circuit chip C2 with an upper surface of the first lower test pad 352 being coplanar with the upper surface of the circuit chip C2. The first upper test pad 351 included in the first test pattern 101 may be a part of the test pads disposed on the lower surface of the memory chip C1. Similarly, the first lower test pad 352 included in the first test pattern 101 may be a part of the test pads arranged on the upper surface of the circuit chip C2.

The first upper test pad 351 may be formed in the same process operation as the cell bonding pad 201. In an embodiment, the first upper test pad 351 may include the same material as the material forming the cell bonding pad 201. For example, the first upper test pad 351 may include copper.

The first lower test pad 352 may be formed in the same process operation as the peripheral bonding pad 202. In an embodiment, the first lower test pad 352 may include the same material as the material forming the peripheral bonding pad 202 or the first upper test pad 351. For example, the first lower test pad 352 may include copper.

In an embodiment, the number of first upper test pads 351 and first lower test pads 352 included in the first test pattern 101 may be the same. The lower surface of the first upper test pad 351 may contact the upper surface of a corresponding first lower test pad 352.

The first upper test contact 353 may be connected to the first upper test pad 351. In an embodiment, two first upper test contacts 353 may be connected to one first upper test pad 351. The first upper test contact 353 may be formed in the same process operation as the cell bonding contact 341. In an embodiment, the first upper test contact 353 may include the same material as the material forming the cell bonding contact 341. For example, the first upper test contact 353 may include tungsten. The first upper test contact 353 may include a material different from the material forming the first upper test pad 351.

The first upper conductive layer 354 may be connected to the first upper test contact 353. The first upper conductive layer 354 may be connected to one or more first upper test contacts 353. In an embodiment, one first upper conductive layer 354 may be connected to two first upper test contacts 353. The first upper conductive layer 354 may be connected to first upper test contacts 353 which are connected to different first upper test pads 351. One first upper test pad 351 may be connected to another first upper test pad 351 through a first upper test contact 353, a first upper conductive layer 354 connected to the first upper test contact 353, and another first upper test contact 353 connected to the first upper conductive layer 354 at a different location from the first upper test contact 353.

The first connection contacts 355 may be connected to different first upper conductive layers 354. In an embodiment, the first connection contacts 355 may include the same material as the material forming the fourth contact 317. Although FIG. 3 illustrates two first connection contacts 355 connected to one first upper conductive layer 354, the embodiments are not limited thereto. Two or more first connection contacts 355 may be connected on the first upper conductive layer 354.

The first probing input pad 232 and output pad 231 may be connected to different first connection contacts 355, respectively. In an embodiment, the first probing input pad 232 and output pad 231 may include the same material as the material forming the fourth wiring 306.

Different voltages may be applied to the first probing input pad 232 and output pad 231, respectively. For example, a first voltage V0 may be applied to the first probing output pad 231, and a second voltage V1 may be applied to the first probing input pad 232. For example, V0 may be zero volts (0V), and V1 may be a voltage greater than 0.

According to embodiments of the present disclosure, the first test pattern 101 may be configured for measuring contact resistance between the first upper test contact 353 and the first upper test pad 351.

For example, if 0V is applied as the first voltage V0 to the first probing output pad 231 and a voltage greater than 0 is applied as the second voltage V1 to the first probing input pad 232, the current may flow from the first probing input pad 232 to the first probing output pad 231. In this case, if a current value output from the first probing output pad 231 is measured, the resistance between the first probing output pad 231 and the first probing input pad 232 may be calculated by Ohm's law.

The resistance between the first probing output pad 231 and the first probing input pad 232 may have a value similar to the resistance obtained by adding the contact resistance between the first upper test contact 353 and the first upper test pad 351 and the resistance of the first upper conductive layer 354 itself. For example, if the number of first connection contacts 355 is large, there may be ignored the resistance of the first connection contact 355 itself, the contact resistance between the first probing input pad 232 or the first probing output pad 231 and the first connection contact 355, and the contact resistance between the first upper conductive layer 354 and the first connection contact 355. In addition, if the first upper test pad 351 and the first lower test pad 352 are made of the same material, most of the current flowing between the first probing input pad 232 and the first probing output pad 231 may flow only through the first upper test pad 351, so the contact resistance between the first upper and lower test pads 351 and 352 may also be ignored.

The first upper conductive layer 354 may have a thickness and length which are preset during the manufacture of the semiconductor device. For example, a length L1 between the first upper test contacts 353 connected to the first upper conductive layer 354 may be a preset value. Therefore, the resistance of the first upper conductive layer 354 itself may be obtained by measuring the length L1 between the first upper test contacts 353 connected to the first upper conductive layer 354.

The contact resistance between the first upper test contact 353 and the first upper test pad 351 may be calculated by subtracting the total resistance of the first upper conductive layer 354 itself from the resistance between the first probing output pad 231 and the first probing input pad 232. If the contact resistance between the first upper test contact 353 and the first upper test pad 351 is divided by the number of first upper test contacts 353, a first resistance may be calculated, which is the contact resistance between one first upper test contact 353 and one first upper test pad 351.

Referring to FIG. 4, the semiconductor device may include a first test pattern 101. The first test pattern 101 may include a first upper test pad 451, a first upper test contact 453, and a first upper conductive layer 454.

The first upper test pad 451 may contact the upper surface of the first insulating layer 321. In an embodiment, no test pad may be disposed under the first upper test pad 451.

The first upper test contact 453 may be connected to the first upper test pad 451. In an embodiment, two first upper test contacts 453 may be connected to one first upper test pad 451.

The first upper conductive layer 454 may be connected to the first upper test contact 453. The first upper conductive layer 454 may be connected to one or more first upper test contacts 453. In an embodiment, one first upper conductive layer 454 may be connected to two first upper test contacts 453. The first upper conductive layer 454 may be connected to first upper test contacts 453 connected to different first upper test pads 451. One first upper test pad 451 may be connected to another first upper test pad 451 through the first upper test contact 453, the first upper conductive layer 454 connected to the first upper test contact 453, and another first upper test contact 453 connected to the first upper conductive layer 454 at a different location from the first upper test contact 453.

A first connection contact 455 may be connected to different first upper conductive layers 454. The first probing input and output pads 231 and 232 may be connected to different first connection contacts 455, respectively.

If a first voltage V0 of zero volts (0 V) is applied to a first probing output pad 231 and a voltage greater than 0 is applied to a first probing input pad 232 as the second voltage V1, current may flow from the first probing input pad 232 to the first probing output pad 231. By measuring the current value output to the first probing output pad 231, there may be calculated a resistance between the first probing output pad 231 and the first probing input pad 232.

The resistance between the first probing output pad 231 and the first probing input pad 232 may have a value similar to a resistance obtained by adding a contact resistance between the first upper test contact 453 and the first upper test pad 451 and a resistance of the first upper conductive layer 454 itself. Since the first test pattern 101 does not include the first lower test pad 352 illustrated in FIG. 3, a contact resistance between the first upper test pad 351 and the first lower test pad 352 illustrated in FIG. 3 may not be considered.

As in the case of the first test pattern 101 illustrated in FIG. 3, the contact resistance between the first upper test contact 453 and the first upper test pad 451 may be calculated by subtracting the total value of the resistance of the first upper conductive layer 454 itself from the resistance between the first probing output pad 231 and the first probing input pad 232. If the contact resistance between the first upper test contact 453 and the first upper test pad 451 is divided by the number of first upper test contacts 453, a first resistance may be calculated, which is a contact resistance between one first upper test contact 453 and one first upper test pad 451.

Referring now to FIG. 5, the semiconductor device may include a second test pattern 102. The second test pattern 102 may include a second upper test pad 551, a second lower test pad 552, a second upper test contact 553, a second lower test contact 556, a second upper conductive layer 554, and a second lower conductive layer 557. The second upper test pad 551 included in the second test pattern 102 may be a part of the test pads disposed on the lower surface of the memory chip C1. Similarly, the second lower test pad 552 included in the second test pattern 102 may be a part of the test pads disposed on the upper surface of the circuit chip C2.

The lower surface of the second upper test pad 551 may contact the upper surface of a corresponding second lower test pad 552. In an embodiment, the number of second upper test pads 551 and second lower test pads 552 included in the second test pattern 102 may be the same.

The second upper test contact 553 may be connected on the second upper test pad 551. The second upper test contact 553 may be disposed only on the second upper test pad 551 closest to a second probing input pad 234 and a second probing output pad 233. In an embodiment, the number of second upper test contacts 553 may be one or more.

The second upper conductive layer 554 may be connected on the second upper test contact 553. The second connection contacts 555 may be connected to different second upper conductive layers 554. In FIG. 5, two second connection contacts 555 are connected to one second upper conductive layer 554, but the embodiments are not limited thereto. Two or more second connection contacts 555 may be connected on the second upper conductive layer 554.

The second probing input pad 234 and the second probing output pad 233 may be connected to different second connection contacts 555, respectively. Different voltages may be applied to the second probing input pad 234 and the second probing output pad 233, respectively. For example, a first voltage V0 may be applied to the second probing output pad 233, and a third voltage V2 may be applied to the second probing input pad 234. For example, V0 may be 0 V, and V2 can be a voltage greater than 0.

The second lower test contact 556 may be connected to the second lower test pad 552. In an embodiment, two second lower test contacts 556 may be connected to one second lower test pad 552. The second lower test contact 556 may be formed in the same process operation as the peripheral bonding contact 331 of FIG. 3. In an embodiment, the second lower test contact 556 may include the same material as the material forming the peripheral bonding contact 331. For example, the second lower test contact 556 may include copper. The second lower test contact 556 may include the same material as the material forming the second lower test pad 552.

The second lower conductive layer 557 may be connected to the second lower test contact 556. The second lower conductive layer 557 may be connected to one or more second lower test contacts 556. In an embodiment, one second lower conductive layer 557 may be connected to two second lower test contacts 556. The second lower conductive layer 557 may be connected to second lower test contacts 556 connected to different second lower test pads 552. The second lower test pad 552 may be connected to another second lower test pad 552 via a second lower test contact 556, a second lower conductive layer 557 connected to the second lower test contact 556, and another second lower test contact 556 connected to the second lower conductive layer 557 at a different location from the second lower test contact 556. In an embodiment, the second lower conductive layer 557 may include the same material as the material forming the second lower test contact 556. For example, the second lower conductive layer 557 may include copper.

According to embodiments of the present disclosure, the second test pattern 102 may be configured for measuring contact resistance between the second lower test contact 556 and the second lower test pad 552.

For example, if a voltage V0 of zero volts (0 V) is applied as the first voltage to the second probing output pad 233 and a voltage greater than 0 is applied as the second voltage V1 to the second probing input pad 234, the current may flow from the second probing input pad 234 to the second probing output pad 233. By measuring the current value output from the second probing output pad 233, the resistance between the second probing output pad 233 and the second probing input pad 234 can be calculated.

The resistance between the second probing output pad 233 and the second probing input pad 234 may have a value similar to a resistance obtained by adding a contact resistance between the second lower test contact 556 and the second lower test pad 552 and a resistance of the second lower conductive layer 557 itself. For example, if a large number of second connection contacts 555 are arranged, the resistance of the second connection contact 555 itself, and the contact resistance between the second probing input pad 234 or the second probing output pad 233 and the second connection contact 555, and the contact resistance between the second upper conductive layer 554 and the second connection contact 555, may be ignored. In addition, if the number of second upper test contacts 553 is large, the resistance of the second upper test contact 553 itself, and the contact resistance between the second upper test pad 551 and the second upper test contact 553 may be ignored. In addition, if the second lower test contact 556 and the second lower conductive layer 557 are made of the same material, the contact resistance between the second lower test contact 556 and the second lower conductive layer 557 may also be ignored.

The second lower conductive layer 557 may be formed to have a preset thickness and length during the manufacture of the semiconductor device. For example, a length L2 between the second lower test contacts 556 connected to the second lower conductive layer 557 may be a preset value. Therefore, the resistance of the second lower conductive layer 557 itself may be obtained by measuring the length L2 between the second lower test contacts 556 connected to the second lower conductive layer 557.

The contact resistance between the second lower test contact 556 and the second lower test pad 552 may be calculated by subtracting the total resistance of the second lower conductive layer 557 itself from the resistance between the second probing output pad 233 and the second probing input pad 234. If the contact resistance between the second lower test contact 556 and the second lower test pad 552 is divided by the number of second lower test contacts 556, there may be calculated a second resistance, which is the contact resistance between one second lower test contact 556 and one second lower test pad 552.

Referring to FIG. 6, the semiconductor device may include a second test pattern 102. The second test pattern 102 may include a second upper test pad 651, a second lower test pad 652, a second upper test contact 653, a second lower test contact 656, a second upper conductive layer 654, and a second lower conductive layer 657.

The second upper test contact 653 and the second upper test pad 651 may be located only on the second lower test pad 652 which is closest to a second probing input pad 234 and a second probing output pad 233. In an embodiment, the number of the second upper test contacts 653 may be one or more.

The second upper conductive layer 654 may be connected to the second upper test contact 653. The second connection contacts 655 may be connected to different second upper conductive layers 654. Two or more second connection contacts 655 may be connected on the second upper conductive layer 654.

The second probing input pad 234 and the second probing output pad 233 may be connected to different second connection contacts 655, respectively. Different voltages may be applied to the second probing input pad 234 and the second probing output pad 233, respectively. For example, a first voltage V0 may be applied to the second probing output pad 233, and a third voltage V2 may be applied to the second probing input pad 234. For example, V0 may be 0V, and V2 may be a voltage greater than 0.

The second lower test contact 656 may be connected to the second lower test pad 652. In an embodiment, two second lower test contacts 656 may be connected to one second lower test pad 652.

The second lower conductive layer 657 may be connected to the second lower test contact 656. The second lower conductive layer 657 may be connected to one or more second lower test contacts 656. In an embodiment, one second lower conductive layer 657 may be connected to two second lower test contacts 656. The second lower conductive layer 657 may be connected to second lower test contacts 656 connected to different second lower test pads 652. One second lower test pad 652 may be connected to another second lower test pad 652 through a second lower test contact 656, a second lower conductive layer 657 connected to the second lower test contact 656, and another second lower test contact 656 connected to the second lower conductive layer 657 at a different location from the second lower test contact 656.

If 0 V is applied to the second probing output pad 233 as a first voltage V0 and a voltage greater than 0 is applied to the second probing input pad 234 as a third voltage V2, current may flow from the second probing input pad 234 to the second probing output pad 233. By measuring the current value output to the second probing output pad 233, there may be calculated a resistance between the second probing output pad 233 and the second probing input pad 234.

The resistance between the second probing output pad 233 and the second probing input pad 234 may have a value similar to a resistance obtained by adding a contact resistance between the second lower test contact 656 and the second lower test pad 652 and a resistance of the second lower conductive layer 657 itself. Since the test pads are not bonded on the second lower test pad 652 except for the second upper test pad 651 arranged at both ends, it may not be required to consider a contact resistance between the second upper test pad 652 and the second lower test pad 652.

Similar to the second test pattern 102 illustrated in FIG. 5, the contact resistance between the second lower test contact 656 and the second lower test pad 652 may be calculated by subtracting the total value of the resistance of the second lower conductive layer 657 itself from the resistance between the second probing output pad 233 and the second probing input pad 234. If the contact resistance between the second lower test contact 656 and the second lower test pad 652 is divided by the number of second lower test contacts 656, there may be calculated a second resistance, which is a contact resistance between one second lower test contact 656 and one second lower test pad 652.

Referring to FIG. 7, the semiconductor device may include a third test pattern 103. The third test pattern 103 may include a third upper test pad 751, a third lower test pad 752, a third upper test contact 753, a third lower test contact 756, a third upper conductive layer 754, and a third lower conductive layer 757. The third upper test pad 751 included in the third test pattern 103 may be a part of the test pads arranged on the lower surface of the memory chip C1. Similarly, the third lower test pad 752 included in the third test pattern 103 may be a part of the test pads arranged on the upper surface of the circuit chip C2.

In an embodiment, the number of the third upper test contact 753, the third upper test pad 751, the third lower test contact 756, and the third lower test pad 752 included in the third test pattern 103 may all be the same. For example, the third upper test contact 753 may be connected to only one corresponding third upper test pad 751. The third upper test pad 751 may be connected to only one corresponding third lower test pad 752. Similarly, the third lower test pad 752 may be connected to only one corresponding third lower test contact 756.

The third upper conductive layer 754 may be connected to the third upper test contact 753. The third upper conductive layer 754 may be connected to one or more third upper test contacts 753. The third upper conductive layer 754 may be connected to a third upper test contact 753 connected to a different third upper test pad 751. One third upper test pad 751 may be connected to another third upper test pad 751 through the third upper test contact 753, the third upper conductive layer 754 connected to the third upper test contact 753, and another third upper test contact 753 connected to the third upper conductive layer 754 at a different location from the third upper test contact 753.

The third lower conductive layer 757 may be connected to the third lower test contact 756. The third lower conductive layer 757 may be connected to one or more third lower test contacts 756. In an embodiment, one third lower conductive layer 757 may be connected to two third lower test contacts 756. The third lower conductive layer 757 may be connected to a third lower test contact 756 connected to a different third lower test pad 752. One third lower test pad 752 may be connected to another third lower test pad 752 through the third lower test contact 756, the third lower conductive layer 757 connected to the third lower test contact 756, and another third lower test contact 756 connected to the third lower conductive layer 757 at a different location from the third lower test contact 756.

The third connection contact 755 may be connected to different third upper conductive layers 754. Although FIG. 7 illustrates two third connection contacts 755 connected to one third upper conductive layer 754, the number of third connection contacts 755 is not limited thereto.

A third probing input pad 236 and a third probing output pad 235 may be connected to different third connection contacts 755, respectively. Different voltages may be applied to the third probing input pad 236 and the third probing output pad 235, respectively. For example, a first voltage V0 may be applied to the third probing output pad 235, and a fourth voltage V3 may be applied to the third probing input pad 236. For example, V0 may be 0V, and V3 may be a voltage greater than 0.

According to embodiments of the present disclosure, the third test pattern 103 may be configured for measuring a resistance between the third probing input pad 236 and the third probing output pad 235.

For example, if a voltage V0 of zero volts (0 V) is applied to the third probing output pad 235 and a voltage greater than 0 is applied as the fourth voltage V3 to the third probing input pad 236, current may flow from the third probing input pad 236 to the third probing output pad 235. By measuring the current value output to the third probing output pad 235, there may be calculated a resistance between the third probing output pad 235 and the third probing input pad 236.

The resistance between the third probing output pad 235 and the third probing input pad 236 may have a value similar to a resistance obtained by adding a contact resistance between the third upper test contact 753 and the third upper test pad 751, a contact resistance between the third upper test pad 751 and the third lower test pad 752, a contact resistance between the third lower test pad 752 and the third lower test contact 756, and a resistance of the third upper conductive layer 754 and the third lower conductive layer 757 themselves. As described above, if the number of third connection contacts 755 is large, the resistance of the third connection contact 755 itself, the contact resistance between the third probing output pad 235 or the third probing input pad 236 and the third connection contact 755, and the contact resistance between the third upper conductive layer 754 and the third connection contact 755 may be ignored.

As described above, the resistance of the third upper conductive layer 754 and the third lower conductive layer 757 themselves can be obtained by measuring the length of the third upper test contact 753 connected to the third upper conductive layer 754 and the length of the third lower test contact 756 connected to the third lower conductive layer 757.

By subtracting the resistance of the third upper conductive layer 754 and the third lower conductive layer 757 themselves from the resistance between the third probing output pad 235 and the third probing input pad 236, it is possible to calculated a contact resistance between the third upper test contact 753 and the third upper test pad 751, a contact resistance between the third upper test pad 751 and the third lower test pad 752, and a contact resistance between the third lower test pad 752 and the third lower test contact 756. That is, the resistance between the third upper test contact 753 and the third lower test contact 756 may be calculated. By dividing the resistance between the third upper test contact 753 and the third lower test contact 756 by the number of third upper test contacts 753 or third lower test contacts 756, there may be calculated a third resistance, which is the resistance between one third upper test contact 753 and one third lower test contact 756.

By subtracting both the first resistance described above with reference to FIG. 3 or FIG. 4 and the second resistance described above with reference to FIG. 5 or FIG. 6 from the third resistance, there may be calculated a contact resistance between the third upper test pad 751 and the third lower test pad 752.

According to embodiments of the present disclosure, the degree of bonding between the third upper test pad 751 and the third lower test pad 752 may be evaluated based on the contact resistance between the third upper test pad 751 and the third lower test pad 752. For example, if the contact resistance between the third upper test pad 751 and the third lower test pad 752 is calculated to be large, there may be determined that the third upper test pad 751 and the third lower test pad 752 are not in good contact, and thus the degree of bonding or the strength of bonding is relatively weak.

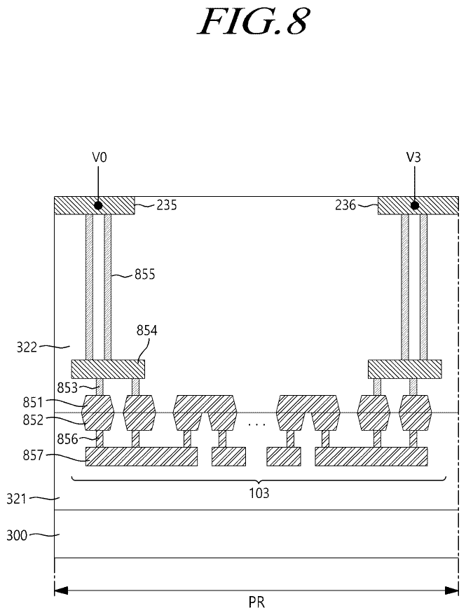

Referring to FIG. 8, the semiconductor device may include a third test pattern 103. The third test pattern 103 may include a third upper test pad 851, a third lower test pad 852, a third upper test contact 853, a third lower test contact 856, a third upper conductive layer 854, and a third lower conductive layer 857.

In an embodiment, the third upper test pad 851 may be bonded with two third lower test pads 852. The third upper test pad 851 may connect two adjacent third lower test pads 852.

In an embodiment, the number of third upper test contacts 853 connected to the third upper conductive layer 854 may be one or more.

The third lower conductive layer 857 may be connected to the third lower test contact 856. The third lower conductive layer 857 may be connected to one or more third lower test contacts 856. In an embodiment, one third lower conductive layer 857 may be connected to two third lower test contacts 856. The third lower conductive layer 857 may be connected to third lower test contacts 856 connected to different third lower test pads 852. The third lower test pad 852 may be connected to another third lower test pad 852 via a third lower test contact 856, a third lower conductive layer 857 connected to the third lower test contact 856, and another third lower test contact 856 connected to the third lower conductive layer 857 at a different location than the third lower test contact 856.

According to embodiments of the present disclosure, the third test pattern 103 may be configured for measuring a resistance between a third probing input pad 236 and a third probing output pad 235.

The resistance between the third probing output pad 235 and the third probing input pad 236 may have a value similar to a resistance obtained by adding a contact resistance between the third upper test pad 851 and the third lower test pad 852, a contact resistance between the third lower test pad 852 and the third lower test contact 856, and a resistance of the third upper conductive layer 854 and the third lower conductive layer 857 themselves. As described above, if the number of the third connection contacts 855 and the third upper test contacts 853 is large, the resistance due to the third connection contacts 855 and the third upper test contacts 853 can be ignored.

By subtracting a resistance of the third upper conductive layer 854 and the third lower conductive layer 857 from the resistance between the third probing output pad 235 and the third probing input pad 236, there may be calculated a contact resistance between the third upper test pad 851 and the third lower test pad 852 and a contact resistance between the third lower test pad 852 and the third lower test contact 856. That is, there may be determined a fourth resistance, which is a resistance between the third upper test pad 851 and the third lower test contact 856.

By subtracting a value obtained by multiplying the second resistance described above with reference to FIG. 5 or FIG. 6 by the number of second lower test contacts 556 and 656 from the fourth resistance, the contact resistance between the third upper test pad 851 and the third lower test pad 852 may be calculated.

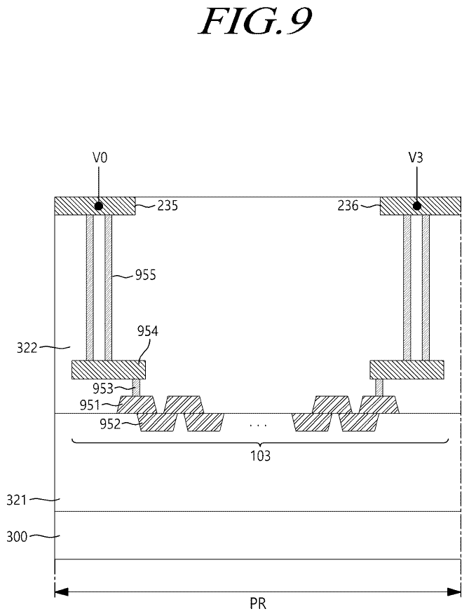

Referring to FIG. 9, the semiconductor device may include a third test pattern 103. The third test pattern 103 may include a third upper test pad 951, a third lower test pad 952, a third upper test contact 953, and a third upper conductive layer 954.

In an embodiment, the third upper test pad 951 may be bonded to two adjacent third lower test pads 952, and the third lower test pad 952 may be bonded to two adjacent third upper test pads 951.

In an embodiment, the number of third upper test contacts 953 connected to the third upper conductive layer 954 may be one or more.

According to embodiments of the present disclosure, the third test pattern 103 may be configured for measuring a resistance between a third probing input pad 236 and a third probing output pad 235.

The resistance between the third probing output pad 235 and the third probing input pad 236 may have a value similar to a contact resistance between the third upper test pad 951 and the third lower test pad 952. As described above, if the third connection contact 955 and the third upper test contact 953 are arranged in large numbers, the resistance due to the third connection contact 955 and the third upper test contact 953 may be ignored.

That is, by measuring the resistance between the third probing output pad 235 and the third probing input pad 236, there may be directly measured the contact resistance between the third upper test pad 951 and the third lower test pad 952.

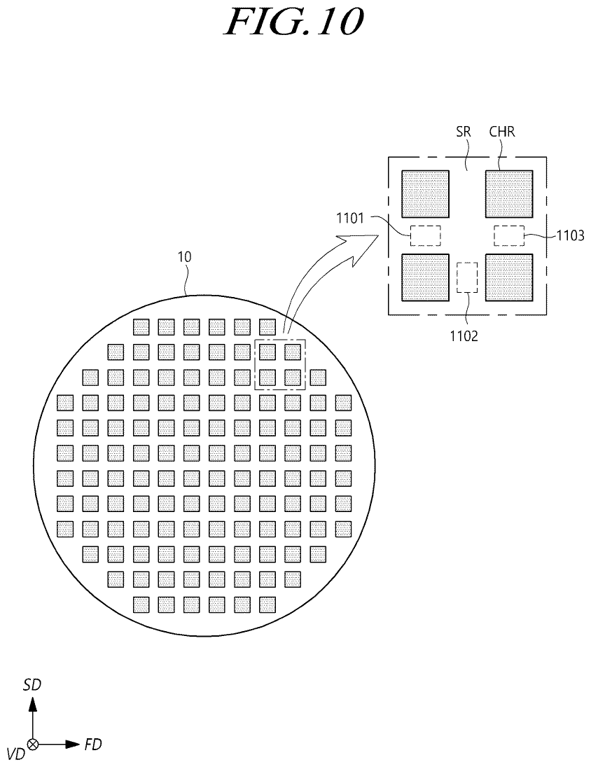

FIG. 10 illustrates another planar structure of a semiconductor device according to embodiments of the present disclosure.

Referring to FIG. 10, a wafer 10 may include a chip region CHR arranged in a first direction FD and a second direction SD, and a scribe lane region SR around the chip region CHR.

In an embodiment, a first test pattern 1101, a second test pattern 1102, and a third test pattern 1103 may be disposed in the scribe lane region SR. The first test pattern 1101, the second test pattern 1102, and the third test pattern 1103 may be substantially the same as the first test pattern 101, the second test pattern 102, and the third test pattern 103 described above with reference to FIGS. 3 to 9, respectively.

Referring again to FIGS. 1 to 9, the first, second, and third test patterns 101, 102 and 103 may be disposed within the chip region CHR. The first test pattern 101 may be configured for measuring a first resistance between a first upper test pad 351 and a first upper test contact 353. The second test pattern 102 may be configured for measuring a second resistance between a second lower test pad 552 and a second lower test contact 556. The third test pattern 103 may be configured for measuring a third resistance between a third upper test contact 753 and a third lower test contact 756. Alternatively, the third test pattern 103 (as shown in FIG. 8), may be configured for measuring a fourth resistance between a third upper test pad 851 and a third lower test contact 856. Alternatively, the third test pattern 103 (see FIG. 9) may be configured for directly measuring the contact resistance between a third upper test pad 951 and a third lower test pad 952.

According to embodiments of the present disclosure, the contact resistance between the third upper test pad 751 and the third lower test pad 752 may be accurately calculated using the first test pattern 101, the second test pattern 102, the third test pattern 103, or a combination thereof. The third upper test pad 751 and the third lower test pad 752 may be formed in the same process operation as the cell bonding pad 201 and the peripheral bonding pad 202, respectively. Therefore, the contact resistance between the cell bonding pad 201 and the peripheral bonding pad 202 may also be calculated in the same manner.

According to the embodiments of the present disclosure, since the contact resistance of bonding pads included in a semiconductor device may be accurately measured, there may be precisely evaluated the degree of bonding between the bonding pads based on the contact resistance of bonding pads.

In addition, the first test pattern 101, the second test pattern 102, and the third test pattern 103 may be implemented in each semiconductor chip. Therefore, there can be individually evaluated the contact resistance and the degree of bonding of the bonding pads for each semiconductor chip.

According to the embodiments of the present disclosure, a method of determining bonding strength between a cell bonding pad and a peripheral bonding pad bonded to each other may include measuring contact resistance between the cell bonding pad and the peripheral bonding pad, and evaluating the bonding strength between the cell bonding pad and the peripheral bonding pad based on the contact resistance.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical idea of this disclosure but to describe the technical idea of this disclosure, the scope of the technical idea of this disclosure is not limited by these embodiments. The protection scope of this disclosure should be interpreted by the claims below, and all technical ideas within the equivalent scope should be interpreted as being included in the scope of the rights of this disclosure. Furthermore, the embodiments may be combined to form additional embodiments.

What is claimed is:

1. A semiconductor device comprising:
a memory chip including a cell bonding pad disposed in a cell region, and upper test pads disposed outside the cell region, the upper test pads including first, second, and third upper test pads;
a circuit chip including a peripheral bonding pad disposed in the cell region, and lower test pads disposed outside the cell region, the lower cell pads including first, second, and third lower test pads; and
test patterns disposed outside the cell region, each of which includes at least a part of the upper test pads or the lower test pads,
wherein the peripheral bonding pad is bonded to the cell bonding pad, and
wherein the test patterns comprise:
a first test pattern in which the first upper test pad, first upper test contacts connected to each of the first upper test pads, and first upper conductive layers connecting the first upper test contacts connected to different first upper test pads are sequentially connected;
a second test pattern in which the second lower test pad, second lower test contacts connected to each of the second lower test pads, and second lower conductive layers connecting the second lower test contacts connected to different second lower test pads are sequentially connected; and
a third test pattern including a third upper conductive layer, a third lower conductive layer, a third upper test contact connected to the third upper conductive layer, a third upper test pad connected to the third upper test contact, a third lower test pad connected to the third upper test pad, and a third lower test contact connected to the third lower test pad and the third lower conductive layer.

2. The semiconductor device of claim 1, further comprising a pair of probing pads each connected to the first test pattern, the second test pattern, or the third test pattern,
wherein the probing pads include a first probing input pad and a first probing output pad connected to the first test pattern at different locations, a second probing input pad and a second probing output pad connected to the second test pattern at different locations, and a third probing input pad and a third probing output pad connected to the third test pattern at different locations,
wherein voltages of different magnitudes are applied to each of the first probing input pad and the first probing output pad, the second probing input pad and the second probing output pad, or the third probing input pad and the third probing output pad,
wherein a resistance between the first probing input pad and the first probing output pad, the second probing input pad and the second probing output pad, or the third probing input pad and the third probing output pad is measured based on a current value flowing between the first probing input pad and the first probing output pad, the second probing input pad and the second probing output pad, or the third probing input pad and the third probing output pad.

3. The semiconductor device of claim 2, wherein voltages of different magnitude are applied to the first probing input pad and the first probing output pad connected to the first test pattern, and a first resistance between the first upper test pad and the first upper test contact is measured based on a current value flowing between the first probing input pad and the first probing output pad,
wherein voltages of different magnitude are applied to the second probing input pad and the second probing output pad connected to the second test pattern, and a second resistance between the second lower test pad and the second lower test contact is measured based on a current value flowing between the second probing input pad and the second probing output pad,
wherein voltages of different magnitude are applied to the third probing input pad and third probing output pad connected to the third test pattern, and a third resistance between the third upper test contact and the third lower test contact is measured based on a current value flowing between the third probing input pad and the third probing output pad, and
wherein a contact resistance between the cell bonding pad and the peripheral bonding pad is measured by subtracting the first resistance and the second resistance from the third resistance.

4. The semiconductor device of claim 1, wherein the first test pattern further includes a first lower test pad bonded to each of the first upper test pads.

5. The semiconductor device of claim 1, wherein the second test pattern further includes a second upper test pad bonded to each of the second lower test pads.

6. The semiconductor device of claim 1, wherein the third upper test pad included in the third test pattern overlaps with two or more of the third lower test pads.

7. The semiconductor device of claim 6, wherein voltages of different magnitude are applied to the second probing input pad and the second probing output pad connected to the second test pattern, and a second resistance between the second lower test pad and the second lower test contact is measured based on a current value flowing between the second probing input pad and the second probing output pad;
wherein voltages of different magnitude are applied to the third probing input pad and the third probing output pad connected to the third test pattern, and a fourth resistance between the third upper test pad and the third lower test contact is measured based on a current value flowing between the third probing input pad and the third probing output pad; and
wherein a contact resistance between the cell bonding pad and the peripheral bonding pad is measured by subtracting the second resistance from the fourth resistance.

8. The semiconductor device of claim 1, wherein the first to third upper test pads are disposed on the same layer as the cell bonding pads.

9. The semiconductor device of claim 1, wherein the memory chip further includes a peripheral region around the cell region, and wherein the first test pattern, the second test pattern and third test pattern are disposed in the peripheral region.

10. The semiconductor device of claim 1, wherein the memory chip further includes a chip region including the cell region and a peripheral region surrounding the cell region, and wherein the first test pattern, the second test pattern, and the third test pattern are disposed in a scribe lane region continuous with the chip region.

11. A semiconductor device comprising:
a memory chip including cell bonding pads disposed in a cell region, and upper test pads disposed outside the cell region;
a circuit chip including peripheral bonding pads disposed in the cell region and bonded to the cell bonding pads, and lower test pads disposed outside the cell region; and
test patterns disposed outside the cell region and including at least a part of the upper test pads or the lower test pads,
wherein at least one of the test patterns includes a part of the upper test pads and a part of the lower test pads,
wherein each of the part of the upper test pads is bonded to two of the part of the lower test pads, and each of the part of the lower test pads is bonded to two of the part of the upper test pads.

12. The semiconductor device of claim 11, further comprising a pair of probing pads connected to at least one of the test patterns,
wherein the probing pads include a probing input pad and a probing output pad connected to at least one of the test patterns at different locations,
wherein voltages of different magnitude are applied to the probing input pad and the probing output pad, and a resistance between the probing input pad and the probing output pad is measured based on a current value flowing between the probing input pad and the probing output pad.

13. The semiconductor device of claim 12, wherein voltages of different magnitudes are applied to the probing input pad and the probing output pad connected to at least one of the test patterns, and a contact resistance between the upper test pad and the lower test pad is measured by measuring a resistance between the probing input pad and the probing output pad based on a current value flowing between the probing input pad and the probing output pad.

14. The semiconductor device of claim 11, wherein the memory chip further includes a peripheral region around the cell region, and at least one test pattern is disposed in the peripheral region.

15. A method of measuring contact resistance for determining bonding strength between a cell bonding pad and a peripheral bonding pad bonded to each other using at least a part of upper test pads including a first upper test pad, a second upper test pad, and a third upper test pad, or lower test pads including a first lower test pad, a second lower test pad, and a third lower test pad comprising:
measuring a first resistance between the first upper test pad and a first upper test contact connected to the first upper test pad;
measuring a second resistance between the second lower test pad and a second lower test contact connected to the second lower test pad;
measuring a third resistance between a third upper test contact and the third lower test contact in a test pattern in which the third upper test contact, the third upper test pad, the third lower test pad, and the third lower test contact are sequentially connected; and
measuring contact resistance between the cell bonding pad and the peripheral bonding pad by subtracting the first and second resistances from the third resistance, and evaluating the bonding strength between the cell bonding pad and the peripheral bonding pad based on the contact resistance.

16. The method of claim 15, wherein measuring a first resistance comprises:
connecting a pair of probing pads to a first test pattern in which the first upper test pad, the first upper test contact, and a first upper conductive layer connecting the first upper test contacts, each of which is connected to a different first upper test pad, are sequentially connected; and
applying different voltages to each of the pair of probing pads.

17. The method of claim 15, wherein measuring a second resistance comprises:
connecting a pair of probing pads to a second test pattern in which the second lower test pad, the second lower test contact, and a second lower conductive layer connecting the second lower test contacts, each of which is connected to a different second lower test pad, are sequentially connected; and
applying different voltages to each of the pair of probing pads.

18. The method of claim 15, wherein, in measuring the third resistance, one third upper test pad overlaps with at least two third lower test pads.
